(19) United States
(12) Patent Application Publication
(10) Pub. No.: US 2026/0171999 A1
(43) Pub. Date: Jun. 18, 2026

(54) BULK ACOUSTIC WAVE DEVICE INCLUDING RAISED FRAME AND PIEZOELECTRIC LAYER WITH ENGINEERED REGION

(71) Applicant: Skyworks Global Pte. Ltd., Singapore (SG)

(72) Inventors: Kwang Jae Shin, Yongin-si (KR); Taecheol Shon, Hwaseong-si (KR); Yanbo He, Irvine, CA (US); Zongliang Cao, Irvine, CA (US)

(21) Appl. No.: 19/412,493

(22) Filed: Dec. 8, 2025

Related U.S. Application Data
(60) Provisional application No. 63/735,676, filed on Dec. 18, 2024.

(51) Int. Cl. H03H 9/02; H03H 9/05; H03H 9/17; H03H 9/56

(52) U.S. Cl. CPC H03H 9/02015; H03H 9/0504; H03H 9/173; H03H 9/568

(57) ABSTRACT

Aspects of this disclosure relate to a bulk acoustic wave that includes a piezoelectric having a lower magnitude effective piezoelectric coefficient in the engineered region than in a main acoustically active region. The bulk acoustic wave device includes a raised frame layer in the engineered region. A resonance associated with the engineered region can be at a lower frequency than a resonant frequency of the main acoustically active region. Related bulk acoustic wave dies, filters, multiplexers, radio frequency modules, radio frequency systems, wireless communication devices, and methods are disclosed.

### CROSS REFERENCE TO PRIORITY APPLICATION

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/735,676, filed Dec. 18, 2024 and titled “BULK ACOUSTIC WAVE DEVICE INCLUDING RAISED FRAME AND PIEZOELECTRIC LAYER WITH ENGINEERED REGION,” the disclosure of which is hereby incorporated by reference in its entirety and for all purposes.

### BACKGROUND

### Technical Field

The disclosed technology relates to acoustic wave devices. Embodiments of this disclosure relate to bulk acoustic wave device having a piezoelectric layer with an engineered region.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to increasing Q and further suppressing spurious mode(s) while meeting other performance specifications for BAW devices.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave device having a main acoustically active region and an engineered region around the main acoustically active region in plan view. The bulk acoustic wave device includes an acoustic reflector, a first electrode, a second electrode, a piezoelectric layer positioned between the first electrode and the second electrode over the acoustic reflector, and a raised frame layer in the engineered region. The piezoelectric layer has a lower magnitude effective piezoelectric coefficient in the engineered region than in the main acoustically active region. A resonance associated with the engineered region is at a lower frequency than a resonant frequency of the main acoustically active region.

The piezoelectric layer can be doped with a dopant. The piezoelectric layer can be an aluminum nitride layer doped with scandium. The piezoelectric layer can be an aluminum nitride layer doped with at least 10% scandium. The piezoelectric layer can be an aluminum nitride layer doped with at least 15% scandium.

The raised frame layer can include a metal. The raised frame layer can include a dielectric. The raised frame layer includes a material selected from the group consisting of an oxide, a nitride, a carbide, or a boride.

The bulk acoustic wave device can include a recessed frame region positioned between the main acoustically active region and the engineered region.

The second electrode can be positioned farther from the acoustic reflector than the first electrode. The raised frame layer can be positioned between the second electrode and the piezoelectric layer in the engineered region. The bulk acoustic wave device can include a second raised frame layer positioned between the second electrode and the piezoelectric layer in the engineered region. The second raised frame layer can extend closer to the main acoustically active region than the raised frame layer. The second raised frame layer can extend beyond the engineered region toward the main acoustically active region. An end of the second raised frame layer closest to the main acoustically active region can terminate in the engineered region. The raised frame layer and the second raised frame layer can both include a same material. The raised frame layer and the second raised frame layer can both include an oxide.

The raised frame layer can extend beyond the engineered region toward the main acoustically active region.

Another aspect of this disclosure is a bulk acoustic wave device having a main acoustically active region and an engineered region around the main acoustically active region in plan view. The bulk acoustic wave device includes an acoustic reflector; a first electrode; a second electrode, the second electrode positioned farther from the acoustic reflector than the first electrode; a piezoelectric layer positioned between the first electrode and the second electrode over the acoustic reflector in at least the main acoustically active region, the piezoelectric layer having a lower magnitude effective piezoelectric coefficient in the engineered region than in the main acoustically active region; and a raised frame structure in the engineered region, the raised frame structure including a first raised frame layer and a second raised frame layer, the first raised frame layer and the second raised frame layer both positioned between the second electrode and the piezoelectric layer in the engineered region, a resonance associated with the engineered region is at a lower frequency than a resonant frequency of the main acoustically active region.

The first raised frame layer and the second raised frame layer can both be oxide layers.

The bulk acoustic wave device can include a recessed frame region between the main acoustically active region and the engineered region.

The raised frame structure can extend beyond the engineered region toward the main acoustically active region.

Another aspect of this disclosure is a bulk acoustic wave device having a main acoustically active region and an engineered region around the main acoustically active region in plan view. The bulk acoustic wave device includes an acoustic reflector; a first electrode; a second electrode, the second electrode positioned farther from the acoustic reflector than the first electrode; a piezoelectric layer positioned between the first electrode and the second electrode over the acoustic reflector in at least the main acoustically active region, the piezoelectric layer having a lower magnitude effective piezoelectric coefficient in the engineered region than in the main acoustically active region; and a raised frame layer positioned between the second electrode and the piezoelectric layer in the engineered region, the raised frame layer extending beyond the engineered region toward the main acoustically active region, a resonance associated with the engineered region being at a lower frequency than a resonant frequency of the main acoustically active region.

Another aspect of this disclosure is an acoustic wave filter for filtering a radio frequency signal. The acoustic wave filter includes a bulk acoustic wave device in accordance with any suitable principles and advantages disclosed herein and a plurality of additional acoustic wave resonators. The bulk acoustic wave device and the plurality of additional acoustic wave resonators are configured to filter the radio frequency signal.

Another aspect of this disclosure is a multiplexer for filtering radio frequency signals. The multiplexer includes a first filter including a bulk acoustic wave device in accordance with any suitable principles and advantages disclosed herein, and a second filter coupled to the first filter at a common node.

Another aspect of this disclosure is a radio frequency module that includes a filter including a bulk acoustic wave device in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave device in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave device in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal at an input of the filter; and filtering the radio frequency signal with a filter that includes a bulk acoustic wave device in accordance with any suitable principles and advantages disclosed herein.

### BRIEF DESCRIPTION OF THE DRAWINGS

Embodiments of this disclosure will now be described, by way of non-limiting example, with reference to the accompanying drawings.

FIG. 1 is a schematic cross-sectional view of a bulk acoustic wave (BAW) device that includes a piezoelectric layer with an engineered region.

FIG. 2 is a plot of frequency responses of different regions of the BAW device of FIG. 1.

FIG. 3A is a plot of frequency responses associated with different widths of an engineered region of the BAW device of FIG. 1.

FIG. 3B is a plot of quality factor (Q) over frequency with and without a mode associated with the engineered region of FIG. 1.

FIG. 4A is a schematic cross-sectional view of a BAW device with two raised frame layers according to an embodiment. FIGS. 4B and 4C are example top plan views of the BAW device of FIG. 4A.

FIG. 5A is a schematic cross-sectional view of a portion of a BAW device with a raised frame layer that extends beyond an engineered region toward a center of the BAW device according to an embodiment.

FIG. 5B is a schematic cross-sectional view of a portion of a BAW device with a raised frame layer that terminates within an engineered region according to an embodiment.

FIG. 6 is a schematic cross-sectional view of a BAW device with a raised frame layer that extends beyond an engineered region toward a center of the BAW device according to an embodiment.

FIG. 7A is a schematic cross-sectional view of a portion of a BAW device stack with mass loading layers over an engineered region of a piezoelectric layer according to an embodiment.

FIG. 7B is a schematic cross-sectional view of a portion of a BAW device stack with mass loading layers over an engineered region of a piezoelectric layer according to another embodiment.

FIGS. 8A, 8B, and 8C are schematic cross-sectional diagrams of respective portions of BAW devices with mass loading layers over an engineered region of a piezoelectric layer according to embodiments.

FIG. 9A is a schematic block diagram of an oscillator that includes a BAW device according to an embodiment.

FIG. 9B is a schematic block diagram of a sensor that includes a BAW device according to an embodiment.

FIG. 10A is a schematic diagram of a ladder filter that includes one or more BAW resonators according to an embodiment. FIG. 10B is schematic diagram of a band pass filter.

FIGS. 11A, 11B, 11C, and 11D are schematic diagrams of multiplexers that include a filter with one or more BAW resonators according to an embodiment.

FIGS. 12, 13, and 14 are schematic block diagrams of modules that include a filter with one or more BAW resonators according to an embodiment.

FIG. 15 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

Increasing the quality factor (Q) of a given bulk acoustic wave (BAW) resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices disclosed herein can achieve improved performance by engineering a region of a piezoelectric layer. Such engineering can degrade crystallinity of the engineered region of the piezoelectric layer relative to an active piezoelectric region of the piezoelectric layer in certain applications.

BAW devices can include frame structures. A frame structure is a structure that adjusts mass loading in a portion of a BAW device over an acoustic reflector. A frame structure can include a raised frame structure that adds mass loading and/or a recessed frame structure that reduces mass loading. A raised frame structure can include an additional layer and/or a thicker portion of layer that increases mass loading in a portion of a BAW device relative to a main acoustically active region. In some applications, a raised frame layer can include a different material than layers in contact with the raised frame layer. In some applications, a raised frame layer can include a same material as a layer in contact with the raised frame layer. A raised frame structure can be a multi-layer structure that includes two or more raised frame layers. A recessed frame structure can include a thinner portion of a layer of a BAW device that decreases mass loading in a portion of the BAW device relative to a main acoustically active region. The main acoustically active region can be a region of a BAW device that generates a main resonant frequency. The main acoustically active region can be free from frame structures. Certain BAW devices include a frame structure around the main acoustically active region of the BAW device. Such a frame structure can be included around a periphery of the BAW device. In certain applications, the frame structure can surround the main acoustically active region in plan view. In some other applications, the frame structure can be around some but not all of the main acoustically active region in plan view.

A BAW device can include a first electrode, a second electrode, and a piezoelectric layer positioned between the first and second electrodes. A frame structure, such as a raised frame and/or a recessed frame, can be positioned around a main acoustically active region of the BAW device to reduce lateral energy leakage from the main acoustically active region. A region of the BAW device that includes the frame structure can be referred to as a frame region. A raised frame structure can create a resonance at a frequency that is below a resonant frequency of the main acoustically active region of the BAW device in certain applications. This resonance can be below a main resonant frequency of the BAW device. A resonance associated with the raised frame structure can be referred to as a raised frame mode. The raised frame mode can be undesirable in certain applications.

This disclosure provides technical solutions that can suppress and/or eliminate raised frame modes. At the same time, technical solutions disclosed herein can maintain a desired electromechanical coupling coefficient (kt2) and significantly increase a quality factor (Q) of a BAW device. BAW devices disclosed herein include an engineered region of a piezoelectric layer that can suppress a frame mode of a frame structure. These BAW devices can be referred to as having an engineered passive frame. A region of these BAW devices with the engineered region of the piezoelectric layer can be referred to as the engineered region of the BAW device. BAW devices disclosed herein can achieve significant performance improvements over other BAW devices. Filters that include BAW devices disclosed herein can provide improved performance in a variety of applications, such as but not limited to fifth generation (5G) New Radio (NR) applications. BAW devices disclosed herein can improve performance in applications where a plurality of filters are connected together with each other.

A piezoelectric layer of a BAW device can be doped to adjust resonant frequency and/or increase kt2. At certain relatively high doping concentrations (e.g., doping of greater than 10% scandium or doping of greater than 15% scandium), stiffness of the engineered region of the piezoelectric layer can be sufficiently high such that there is a resonance associated with the frame region that is above a resonant frequency of the main acoustically active region. This can degrade Q of the BAW device at a frequency of the resonance associated with the engineered region.

Aspects of this disclosure relate to a BAW device with a raised frame structure that overlaps with an engineered region of the piezoelectric layer over an acoustic reflector. The piezoelectric layer can be less piezoelectric in the engineered region than in a main acoustically active region of the BAW device. The engineered region can suppress a frame mode of the frame structure. The raised frame structure of embodiments of this disclosure can provide sufficient mass loading such that a resonance associated with the engineered region is at a lower frequency than a resonant frequency of a main acoustically active region of the BAW device, even with relatively high doping concentrations in the piezoelectric layer. This can contribute to achieving a high Q.

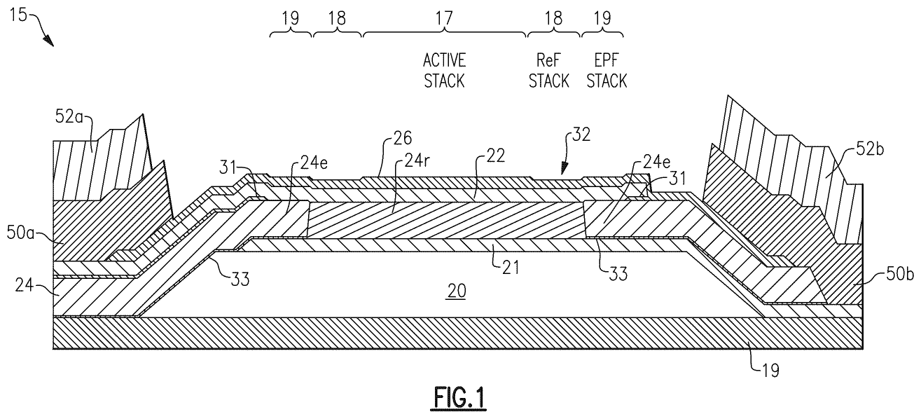

FIG. 1 is a cross-sectional side view of a BAW device 15. The BAW device 15 includes a main acoustically active region 17, a recessed frame region 18, and an engineered passive frame region 19. As illustrated in FIG. 1, the BAW device 15 includes a support substrate 19, an acoustic reflector (e.g., a cavity 20), a first electrode 21, a second electrode 22, a piezoelectric layer 24, a passivation layer 26, a raised frame structure 31, and a recessed frame structure 32.

The piezoelectric layer 24 includes an engineered region 24e. The engineered region 24e can have little or no piezoelectric activity during operation of the BAW device 15. The engineered region 24e can be referred to as a passive piezoelectric region.

A region of the piezoelectric layer 24 that is not engineered can be referred to as an active piezoelectric region 24r of the piezoelectric layer 24. The piezoelectric layer 24 has a significantly higher bulk piezoelectric effect in the active piezoelectric region 24r than in the engineered region 24e. The active piezoelectric region 24r can be referred to as an acoustically active region of the piezoelectric layer 24. The active piezoelectric region 24r can be referred to as a regular region of the piezoelectric layer 24.

The first electrode 21, the second electrode 22, and the active piezoelectric region 24r of the piezoelectric layer 24 overlap over the acoustic reflector (e.g., the cavity 20) and generate an acoustic wave in the main acoustically active region 17 of the BAW device 15. The acoustic wave can have a resonant frequency associated with the main acoustically active region 17. The main acoustically active region 17 can have a highest coupling or highest kt2 at the resonant frequency. The resonant frequency of the main acoustically active region 17 can be an operating mode of the BAW device 15 that is used for a filter that includes the BAW device 15. For example, the operating mode of the BAW device 15 can be used for a passband of a bandpass filter that includes the BAW device 15. The layers of the BAW 15 device over the acoustic reflector in the main acoustically active region 17 can be referred to as an active stack.

The BAW device 15 includes the recessed frame structure 32 in the recessed frame region 18. The recessed frame structure 32 can be formed by reducing the thickness of passivation layer 26 in a selected region. The recessed frame structure 32 can be formed by forming the passivation layer 26 with a greater thickness outside of the selected region. In some other applications, a recessed frame structure can be a thinned portion of an electrode, such as a thinned portion of the second electrode 22. The layers of the BAW 15 device over the acoustic reflector in the recessed frame region 18 can be referred to as a recessed frame (ReF) stack.

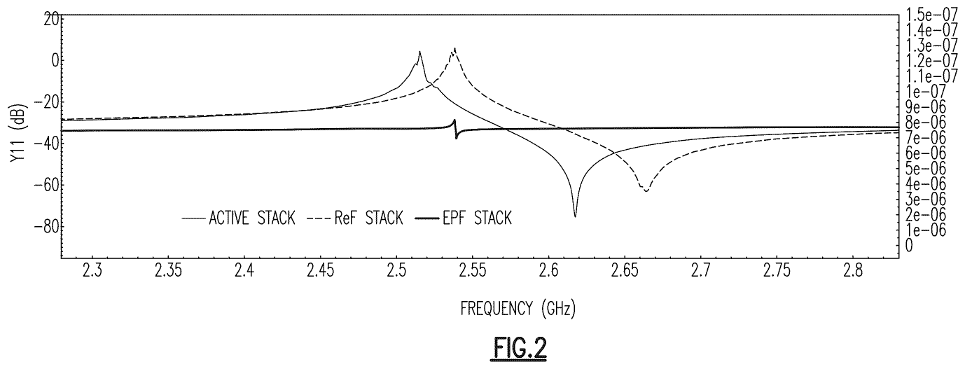

The engineered region 24e of the piezoelectric layer 24 is included in the engineered passive frame region 19. A region of the BAW device 15 that includes the engineered region 24e of the piezoelectric layer can be referred to as the engineered region of the BAW device 15. The layers of the BAW 15 device over the acoustic reflector in the engineered passive frame region 19 can be referred to as an engineered passive frame (EPF) stack. There can be an EPF mode associated with the EPF region 19 in certain applications. More details regarding the EPF mode will be discussed later, for example, with reference to FIG. 2.

In the BAW device 15, the raised frame layer 31 is positioned over the acoustic reflector on an opposite side of the ReF region 18 than the main acoustically active region 17. The raised frame layer 31 can suppress a transverse mode of the BAW device 15. The raised frame layer 31 can reduce or impede propagation of the transverse mode. The raised frame layer 31 can be a metal layer in certain applications. The raised frame layer 31 can be a dielectric layer in some applications. For example, the raised frame layer 31 can be a silicon dioxide layer, an oxide layer, a nitride layer, a carbide layer, or a boride layer in some such applications.

The piezoelectric layer 24 can include a suitable piezoelectric material such as, but not limited to, aluminum nitride (AlN), zinc oxide (ZnO), or lead zirconium titanate (PZT). In certain applications, the piezoelectric layer 24 can be an AlN layer. The piezoelectric material can be doped or undoped. For example, an AlN-based piezoelectric layer can be doped with any suitable dopant, such as, but not limited to, scandium (Sc), chromium (Cr), magnesium (Mg), sulfur (S), yttrium (Y), silicon (Si), germanium (Ge), oxygen (O), hafnium (Hf), zirconium (Zr), titanium (Ti), calcium (Ca), boron (B), carbon (C), europium (Eu), tantalum (Ta), niobium (Nb), or the like. In certain applications, the piezoelectric layer 24 can be AlN based layer doped with Sc. According to some of these applications, the piezoelectric layer 24 of the BAW device 15 can be an AlN based piezoelectric layer doped with 3% to 45% Sc. For example, the piezoelectric layer can be an AlN based layer doped with 10% to 45% Sc. As another example, the piezoelectric layer can be an AlN based layer doped with 10% to 45% Sc. Doping the piezoelectric layer 24 can adjust the resonant frequency. Doping the piezoelectric layer 24 can increase the kt2 of the BAW device 15. Doping to increase the kt2 can be advantageous at higher frequencies where kt2 can be degraded. In certain applications, a BAW device that includes two or more piezoelectric layers can be implemented with any suitable principles and advantages disclosed herein.

The engineered region 24e of the piezoelectric layer 24 can have a lower magnitude effective piezoelectric coefficient than the active piezoelectric region 24r of the piezoelectric layer 24. For example, the engineered region 24e of the piezoelectric layer 24 can have an effective piezoelectric coefficient with a magnitude that is less than 50%, less than 20%, or less than 10% of the magnitude of the effective piezoelectric coefficient of the active piezoelectric region 24r of the piezoelectric layer 24. Even though engineered region 24e of BAW devices of this disclosure may have little or no piezoelectric response, such an engineered region can be considered part of a piezoelectric layer of a BAW device of this disclosure.

The effective piezoelectric coefficient of the engineered region 24e can be an aggregate piezoelectric coefficient for the entire engineered region 24e. The aggregate magnitude of the piezoelectric polarization vectors in the engineered region 24e should be less than the magnitude in the active piezoelectric region 24r. The lower magnitude effective piezoelectric coefficient can be a result of the non-aligned nature of piezoelectric material crystal orientations within the engineered region 24e causing a lower aggregate magnitude of the piezoelectric polarization vectors than in the active piezoelectric region 24r.

The effective piezoelectric coefficient can be an effective piezoelectric coupling coefficient (e33), for example. The engineered region 24e of the piezoelectric layer 24 can suppress the frame mode associated with the raised frame layer 31. BAW devices with an engineered region of a piezoelectric layer and a frame structures (e.g., the frame structure 31) disclosed herein can enable frame mode suppression, transverse mode suppression, and lateral mode suppression.

The piezoelectric layer 24 has a different structure in the engineered region 24e than in the active piezoelectric region 24r. The piezoelectric layer 24 can have deteriorated crystallinity in the engineered region 24e relative to in the active piezoelectric region 24r. The piezoelectric layer 24 can be amorphous in the engineered region 24r. The engineered region 24e of the piezoelectric layer 24 can have a lack of a preferred orientation of the c-axis and/or a random grain orientation. In some instances, the c-axis of the piezoelectric layer 24 in the engineered region 24e can be oriented at an angle in a range from 90° to 150° to relative to a c-axis of the piezoelectric layer 24 in the active piezoelectric region 24r. The engineered region 24e of the piezoelectric layer 24 can have a defect laden structure containing features, such as dislocations and/or stacking faults, which decrease the piezoelectric response of the piezoelectric layer 24 in the engineered region 24e. In some instances, the engineered region 24e of the piezoelectric layer 24 can have nearly equal volumes of c-axis oriented regions of opposite polarity. The structure of the piezoelectric layer 24 in the engineered region 24e can cause the BAW device 15 to exhibit no bulk piezoelectric effect or a weak bulk piezoelectric effect in engineered passive frame region 19. In contrast, the piezoelectric layer 24 can have desirable bulk piezoelectric properties in the active piezoelectric region 24r.

The engineered region 24e can be formed in any suitable manner. For example, a seed layer 33 can be positioned over portions of the first electrode 21 where the engineered region 24e is to be formed. The seed layer 33 can cause the piezoelectric layer 24 to be engineered in the engineered region 24e. The seed layer 33 can be a material that has poor crystallinity or is crystalline with a poor lattice match to the piezoelectric film applied over the seed layer 33. The piezoelectric layer 24 in the engineered region 24e over the seed layer 33 can have relatively poor bulk piezoelectric properties compared to the piezoelectric layer 24 in the active piezoelectric region 24r. The seed layer 33 can be directly over the first electrode 21. The seed layer 33 can be a layer formed by any suitable process, such as but not limited to atomic layer deposition (ALD), physical vapor deposition (PVD), pulsed laser deposition (PLD), or chemical vapor deposition (CVD). The seed layer 33 can include, but is not limited to, an oxide, a nitride, a carbide, a carbon structure (e.g., graphene or diamond), a boride, or any suitable combination thereof. In certain applications, the seed layer 33 can include one or more of aluminum oxide, silicon, silicon carbide, doped aluminum nitride, undoped aluminum nitride, aluminum, fused silica, boron nitride, diamond, silicon oxycarbide glass, silicon oxynitride glass, boron carbide, graphene, beryllium oxide, gallium nitride, indium nitride, silicon nitride, scandium nitride, or the like. In certain embodiments, the seed layer 33 can be an aluminum nitride layer. In some embodiments, the seed layer 33 can have a thickness that is in a single digit nanometer range. In some embodiments, the seed layer 33 can have a thickness that is in a range from 5 nanometers to 150 nanometers. In some of these embodiments, the seed layer can have a thickness that is in a range from 10 nanometers to 100 nanometers. In certain embodiments, the seed layer 33 can have a thickness of 150 nanometers or less. In certain embodiments, the seed layer 33 can have a thickness of 25 nanometers or less.

In some embodiments, a uniform piezoelectric material can be deposited and then the engineered region 24e of the piezoelectric material can be modified to be less piezoelectric than the active piezoelectric region 24r. For example, ions can be implanted to modify the structure and properties of the piezoelectric material by ion implantation to form the engineered region 24e. In such embodiments, the piezoelectric material can be engineered from a side opposite the first electrode 21.

The first electrode 21 can be referred to as a lower electrode. The first electrode 21 can have a relatively high acoustic impedance. The first electrode 21 can include molybdenum (Mo), tungsten (W), ruthenium (Ru), chromium (Cr), iridium (Ir), platinum (Pt), or any suitable alloy and/or combination thereof. Similarly, the second electrode 22 can have a relatively high acoustic impedance. The second electrode 22 can include Mo, W, Ru, Cr, Ir, Pt, or any suitable alloy and/or combination thereof. The second electrode 22 can be formed of the same material as the first electrode 21 in certain applications. The second electrode 22 can be referred to as an upper electrode. The thickness of the first electrode 21 can be approximately the same as the thickness of the second electrode 22 in the main acoustically active region 17 of the BAW device 15.

The passivation layer 26 can be a silicon dioxide layer. The passivation layer 26 can be any other suitable passivation layer, such as aluminum oxide, silicon carbide, aluminum nitride, silicon nitride, silicon oxynitride, or the like. The passivation layer 26 can include a dielectric material.

The support substrate 19 can be a semiconductor substrate. For example, the support substate 19 can be a silicon substrate. The support substrate 19 can be any other suitable support substrate, such as a substrate of quartz, silicon carbide, sapphire, glass, gallium arsenide, or any suitable ceramic (e.g., spinel, alumina, etc.).

A first interconnect structure can include one or more conductive layers such as a first conductive layer 50a and a second conductive layer 52a. Similarly, a second interconnect structure can include one or more conductive layers such as a first conductive layer 50b and a second conductive layer 52b. The first conductive layers 50a, 50b and the second conductive layers 52a, 52b can each include a material suitable for interconnecting the BAW device 15 and one or more other component (e.g., another resonator) in a filter, an external component, or a ground connection. The first conductive layers 50a, 50b and/or the second conductive layers 52a, 52b can be highly conductive. For example, the first conductive layers 50a, 50b and/or the second conductive layers 52a, 52b can be more electrically conductive than the first electrode 21 and/or the second electrode 22. In some embodiments, the first conductive layers 50a, 50b and/or the second conductive layers 52a, 52b can include one or more of gold (Au), titanium (Ti), copper (Cu), aluminum (Al), or tungsten (W).

The cavity 20 (e.g., an air cavity) can be formed between the support substrate 19 and the first electrode 21. The cavity 20 is an example of an acoustic reflector. The BAW device 15 can be a film bulk acoustic wave resonator (FBAR). In some other embodiments, there can be a solid acoustic mirror in place of the cavity 20 and such a BAW device can be a BAW solidly mounted resonator (SMR).

In certain applications, the piezoelectric layer 24 of the BAW device 15 includes an aluminum nitride layer doped with scandium. With relatively high scandium doping (e.g., doping of greater that 10% scandium or doping of greater than 15% scandium), stiffness of the engineered region 24e of the piezoelectric layer can be sufficiently high such that there is a resonance mode of the EPF stack in the EPF region 19. The resonance associated with the EPF region 19 can be above a resonant frequency of the main acoustically active region 17. This can degrade Q of the BAW device 15 at a frequency of the resonance of the EPF region 19.

FIG. 2 is a plot of frequency responses of different regions of the BAW device of FIG. 1. These frequency responses can be associated with the main acoustically active region 17, the recessed frame region 18, and the engineered passive frame region 19 of the BAW device 15. For these simulations, the piezoelectric layer 24 of the BAW device 15 includes an aluminum nitride layer doped with scandium. The doping concentration of scandium can be relatively high (e.g., greater than 10% or greater than 15%). As shown in FIG. 2, the EPF stack can create a resonance that is above the resonant frequency of the active stack. FIG. 2 also illustrates that the resonance of the EPF stack can be below the resonant frequency of the ReF stack. The resonance of the EPF stack shown in FIG. 2 is also below the anti-resonant frequency of the active stack.

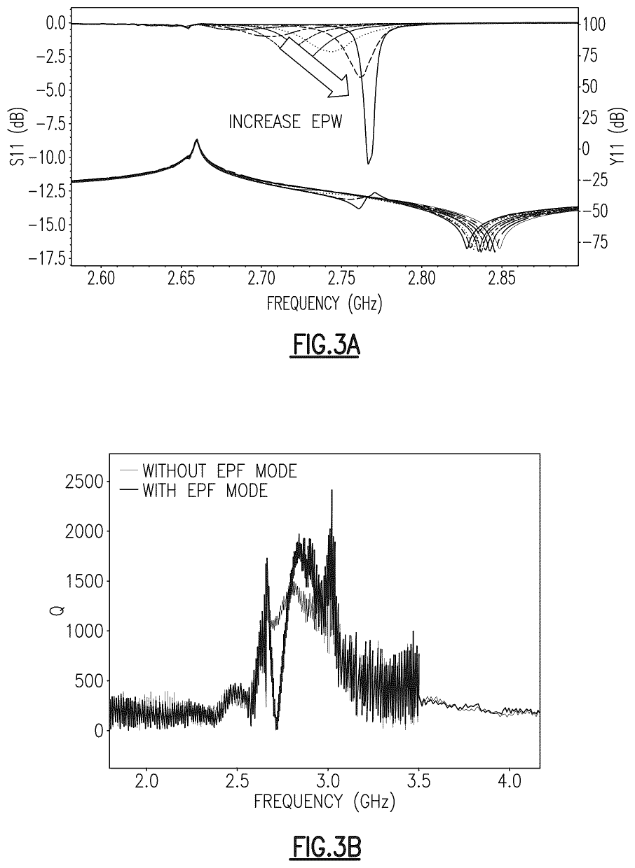

FIG. 3A is a plot of frequency responses associated with different widths of an engineered passive frame region 19 of the BAW device 15 of FIG. 1. The curves in FIG. 3B indicate that as a width of the engineered passive frame region 19 increases, there can be a drop in Q. The drop in Q can be at and/or around a frequency of a resonance of the engineered passive frame region 19.

Increasing the width of the engineered passive frame region 19 of the BAW device 15 can degrade Q, for example, as indicated by FIG. 3A. Other measurement data indicates that increasing a width of the recessed frame region 18 can degrade Q.

FIG. 3B is a plot of Q over frequency with and without a mode associated with the engineered passive frame region 19 of the BAW device 15 of FIG. 1. This plot indicates that a resonance mode associated with the engineered passive frame region 19 can degrade Q. Embodiments of this disclosure relate to bringing the resonance mode associated with the engineered passive frame region below the resonant frequency of the main acoustically active region of a BAW device. This can reduce and/or eliminate Q degradation of the BAW device associated with resonance of the engineered passive frame region.

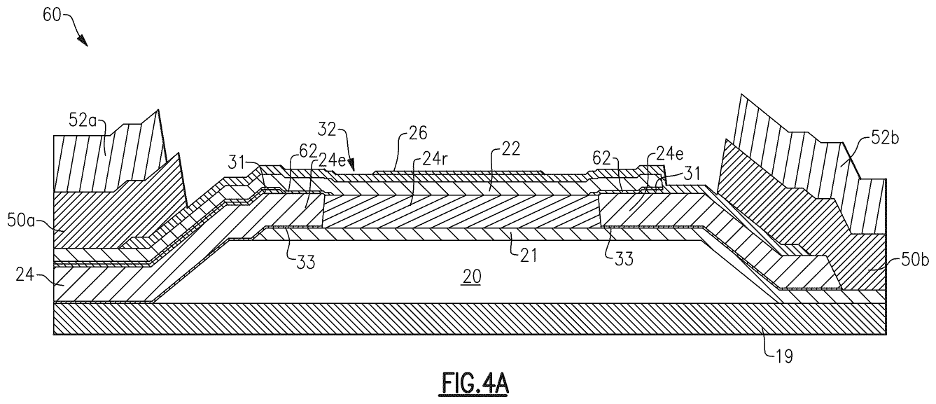

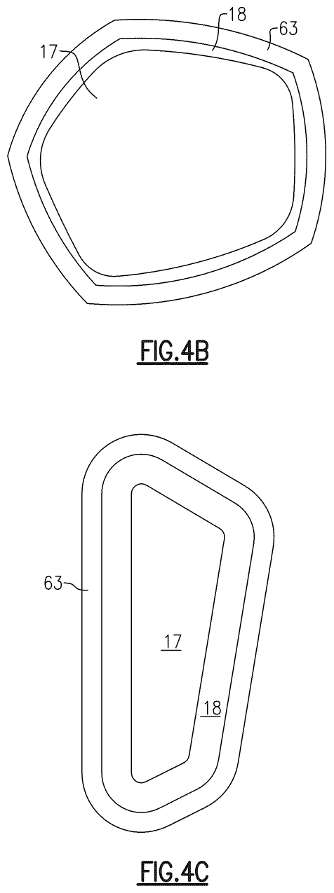

FIG. 4A is a schematic cross-sectional view of a BAW device 60 with two raised frame layers 31 and 62 according to an embodiment. The BAW device 60 is similar to the BAW device 15 of FIG. 1, except that the BAW device 60 includes a second raised frame layer 62. The second raised frame layer 62 overlaps with the raised frame layer 31. As illustrated in FIG. 4A, the second raised frame layer 62 also extends beyond the raised frame layer 31 toward the main acoustically active region of the BAW device 60. The second raised frame layer 62 can extend beyond the engineered region 24e of the piezoelectric layer toward the main acoustically active region of the BAW device 60. An end portion of the second raised frame layer 62 can overlap with the active piezoelectric region 24r of the piezoelectric layer 24.

The raised frame layer 31 and the second raised frame layer 62 can provide sufficient mass loading such that a resonance associated with the engineered region 24e of the piezoelectric layer 24 is below the resonant frequency of the main acoustically active region of the BAW device 60. Accordingly, the BAW device 60 can achieve a relatively high Q that is not significantly degraded by the resonance mode associated with the engineered region 24e of the piezoelectric layer 24.

The second raised frame layer 62 can be any suitable material for mass loading, such as but not limited to a metal layer or a dielectric layer (e.g., a silicon dioxide layer, an oxide layer, a nitride layer, a carbide layer, or a boride layer). The raised frame layer 31 can be any suitable material for mass loading, such as but not limited to a metal layer or a dielectric layer (e.g., a silicon dioxide layer, an oxide layer, a nitride layer, a carbide layer, or a boride layer). The raised frame layer 31 and the second raised frame layer 62 can be formed of a same material in certain applications. The raised frame layer 31 and the second raised frame layer 62 can be formed of different materials in some other applications.

In certain embodiments, the raised frame layer 31 and the second raised frame layer 62 can both be silicon dioxide layers. In some such embodiments, the passivation layer 26 can also be a silicon dioxide layer. In some of these embodiments, the first electrode 21 and the second electrode 22 can both be ruthenium electrodes.

In certain embodiments, the piezoelectric layer 24 can be doped with a dopant. For example, the piezoelectric layer 24 can be aluminum nitride layer doped with scandium. In this example, the doping concentration of scandium can be at least 10%. In some instances, the doping concentration of scandium can be at least 15%. The raised frame layers 31 and 62 can provide sufficient mass loading such that a resonance associated with an engineered passive frame region is below a resonant frequency of the main acoustically active region of the BAW device 60 even with such doping concentrations of at least 10% scandium or at least 15% scandium.

FIGS. 4B and 4C are example top plan views of the BAW device 60 of FIG. 4A. FIG. 4B illustrates the BAW device 60 having a pentagon shape with curved sides in plan view. FIG. 4C illustrates the BAW device 60 having another shape in plan view. A BAW device in accordance with any suitable principles and advantages disclosed herein can have a shaped in plan view illustrated in FIG. 4C or 4D. A BAW device in accordance with any suitable principles and advantages disclosed herein can have any other suitable shape in plan view, such as a semi-elliptical shape, a semi-circular shape, a circular shape, an ellipsoid shape, a quadrilateral shape, or a quadrilateral shape with curved sides.

Regions of the BAW device 60 where the piezoelectric layer 24 is positioned between the first electrode 21 and the second electrode 22 over the acoustic reflector 20 are shown in FIGS. 4B and 4C. In FIGS. 4B and 4C, a main acoustically active region 17, a recessed frame region 18, and a raised frame region 63 are illustrated. The main resonant frequency of the BAW device 60 is generated by the main acoustically active region 17. The recessed frame 32 is included in the recessed frame region 18. The raised frame layer 31 and the second raised frame layer 62 are included in the raised frame region 63. The raised frame region 63 can be or include an engineered passive frame region. In some instances, an engineered passive frame region can include some or all of the recessed frame region 18 when an engineered region of the piezoelectric layer overlaps with a recessed frame structure.

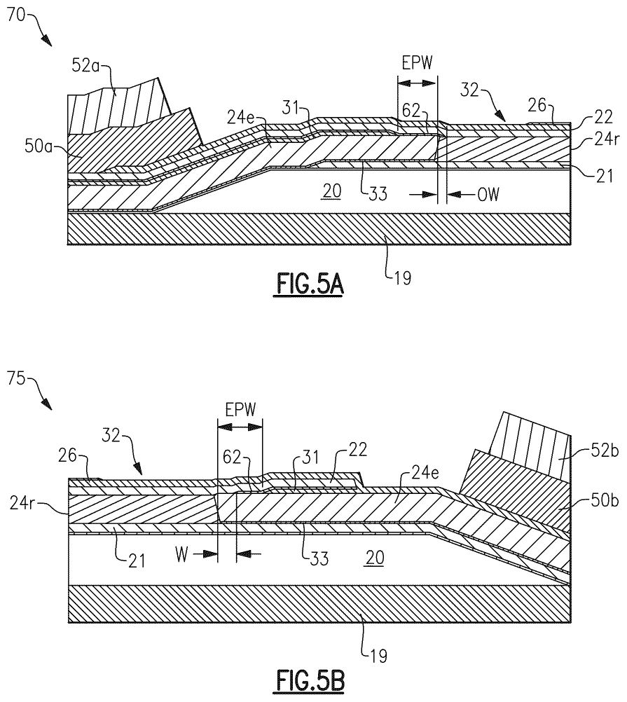

The second raised frame layer 62 can extend beyond the engineered region 24e of the piezoelectric layer 24 and have an end potion overlap with the active piezoelectric region 24r in certain applications. An example of a portion of a BAW device with such a second raised frame layer is shown in FIG. 5A. An end of the second raised frame layer 62 closest to the main acoustically active region 17 can terminate at a point that overlaps with the engineered region 24e of the piezoelectric layer 24 in some other applications. An example of a portion of a BAW device with such a second raised frame layer is shown in FIG. 5B.

FIG. 5A is a schematic cross-sectional view of a portion of a BAW device 70 with a second raised frame layer 62 that extends beyond an engineered region 24e of a piezoelectric layer 24 toward a center of the BAW device 70 according to an embodiment. An end portion of the second raised frame layer 62 of the BAW device 70 overlaps with the active piezoelectric region 24r of the piezoelectric layer 24r for an overlap width OW. The BAW device 70 has a width EPW where the engineered region 24e of the piezoelectric layer 24 is free from the raised frame layer 31. The second raised frame layer 62 can overlap with the active piezoelectric region 24r on one or both sides of the BAW device 70. For example, the second raised frame layer 62 can overlap with the active piezoelectric region 24r of the piezoelectric layer 24 on a second electrode 22 connection side (e.g., as shown in FIG. 5A) and on a first electrode 21 connection side in some applications.

FIG. 5B is a schematic cross-sectional view of a portion of a BAW device 75 with a second raised frame layer 62 that terminates at a point that overlaps with the engineered region 24e of the piezoelectric layer 24 according to an embodiment. The engineered region 24e is free from the raised frame layer 31 and the second raised frame layer 62 in the BAW device 75 for a width W. The BAW device 75 has a width EPW where the engineered region 24e of the piezoelectric layer 24 is free from the raised frame layer 31. The second raised frame layer 62 can terminate over the engineered region 24r on one or both sides of the BAW device 75. For example, the second raised frame layer 62 can terminate over the engineered region 24e of the piezoelectric layer 24 on a first electrode 21 connection side (e.g., as shown in FIG. 5B) and on a second electrode 22 connection side.

In some instances, a BAW device can include features of the BAW device 70 on one electrode connection side and features of the BAW device 75 on another electrode connection side.

FIG. 6 is a schematic cross-sectional view of a BAW device 80 with a raised frame layer 82 that extends beyond an engineered region 24e of the piezoelectric layer toward a center of the BAW device 80 according to an embodiment. An end portion 84 of the raised frame layer 82 overlaps with the active piezoelectric region 24r of the piezoelectric layer 24 in the BAW device 80. As illustrated in FIG. 6, the raised frame layer 82 is positioned between the piezoelectric layer 24 and the second electrode 22.

The BAW device 80 can include a single raised frame layer, which is the raised frame layer 82. The raised frame layer 82 can provide sufficient mass loading such that a resonance associated with the engineered region 24e of the piezoelectric layer is below the resonant frequency of the main acoustically active region of the BAW device 80. This can contribute to the BAW device 80 achieving a relatively high Q over a desired frequency range. With the mass loading from the raised frame layer 82, the piezoelectric layer 24 can have a relatively high doping concentration and a resonance associated with the engineered region 24e can be below the resonant frequency of the main acoustically active region in the BAW device 80.

The raised frame layer 82 can include any suitable material for providing mass loading. The raised frame layer 82 can include any of the materials of the raised frame layer 31 discussed above. The raised frame layer 82 can include any of the materials of the second raised frame layer 62 discussed above. The raised frame layer 82 can include but is not limited to a metal layer or a dielectric layer, such as an oxide layer, a nitride layer, a carbide layer, a boride layer, or the like.

In certain embodiments, the raised frame layer 82 can be a silicon dioxide layer. In some such embodiments, the passivation layer 26 can also be a silicon dioxide layer. In some of these embodiments, the first electrode 21 and the second electrode 22 can both be ruthenium electrodes.

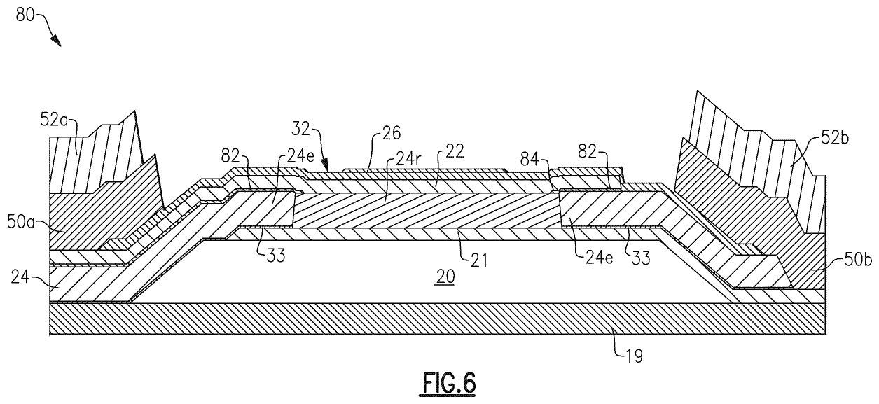

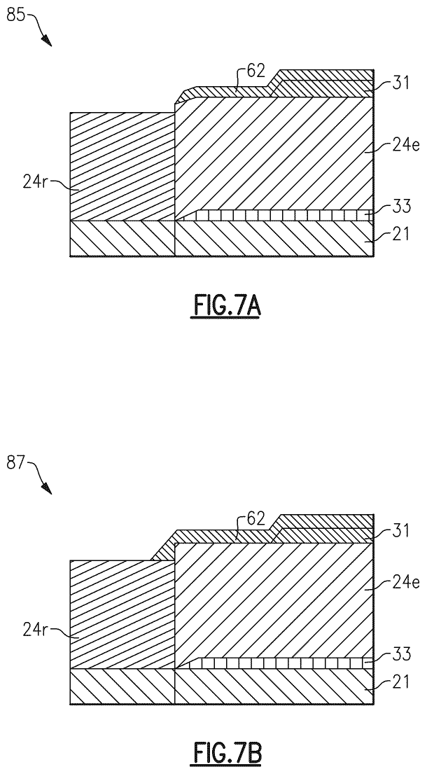

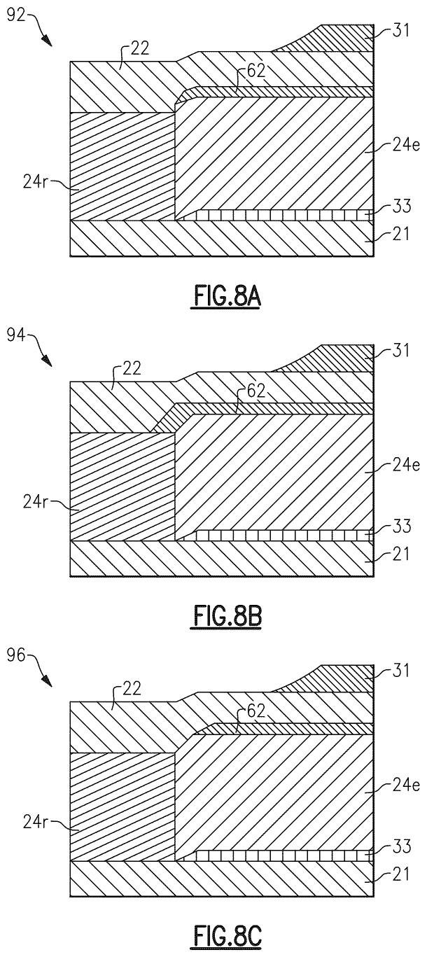

A variety of raised frame structures can result in a BAW device with a resonance associated with an engineered region 24e of the piezoelectric layer 24 that is below the resonant frequency of the main acoustically active region of the BAW device. The resonance associated with an engineered region 24e can be below the resonant frequency of the main acoustically even when the piezoelectric layer has a relatively high doping concentration, such as a doping concentration of at last 10% scandium or at least 15% scandium for an aluminum nitride based piezoelectric layer. Example BAW devices with multi-layer raised frame structures between an engineered region 24e of a piezoelectric layer 24 and a second electrode 22 will be discussed with reference to FIGS. 7A and 7B. Example BAW devices with multi-layer raised frame structures that include two raised frame layers on opposite sides of a second electrode will be discussed with reference to FIGS. 8A, 8B, and 8C. Any suitable principles and advantages of the BAW devices of FIGS. 7A to 8C can be implemented together with each other. Any suitable principles and advantages of the BAW devices of FIGS. 7A to 8C can be implemented together with any other suitable principles and advantages disclosed herein.

FIG. 7A is a schematic cross-sectional view of a portion of a BAW device stack 85 with raised frame layers 31 and 62 over an engineered region 24e of a piezoelectric layer 24 according to an embodiment. The BAW device stack 85 is a portion of a BAW device, and a second electrode can be positioned over the second raised frame layer 62 and the active piezoelectric region 24r of the piezoelectric layer 24 after manufacturing. The second raised frame layer 62 extends to an edge of the engineered region 24e of the piezoelectric layer 24 in the BAW device stack 85. In certain applications, the raised frame layers 31 and 62 can be oxide layers. In some such applications, the raised frame layers 31 and 62 can be silicon oxide layers. In applications where the raised frame layers 31 and 62 are silicon dioxide layers, the raised frame layers 31 and 62 can provide both mass loading and temperature compensation. As also shown in FIG. 7A, the seed layer 33 can have a tapered edge. An edge of the second raised frame layer 62 can also be tapered.

FIG. 7B is a schematic cross-sectional view of a portion of a BAW device stack 87 with mass loading layers 31 and 62 over an engineered region 24e of a piezoelectric layer 24 according to another embodiment. The BAW device stack 87 is like the BAW device stack 85 of FIG. 7A, except that the second raised frame layer 62 extends beyond the engineered region 24e and overlaps with a portion of the active piezoelectric region 24r in the BAW device stack 87. The raised frame layer 62 in the BAW device stack 87 can overlap the entire engineered region 24e over an acoustic reflector even with manufacturing variations.

FIGS. 8A, 8B, and 8C are schematic cross-sectional diagrams of portions of BAW devices 92, 94, and 96, respectively, with mass loading layers over an engineered region of a piezoelectric layer according to embodiments. These figures illustrate a subset of layers of these BAW devices, and the BAW devices 92, 94, and 96 include additional layers such as but not limited to a passivation layer, an acoustic reflector, and a support substrate that are not shown in FIGS. 8A, 8B, and 8C.

The BAW devices 92, 94, and 96 include a raised frame layer 31 over a second electrode 22 and second raised frame 62 layer between the second electrode 22 and the engineered region 24e of the piezoelectric layer 24. The raised frame layer 31 can be a metal layer in the BAW devices 92, 94, and 96. An end of the raised frame layer 31 toward a center of the BAW devices 92, 94, and 96 is tapered. The second raised frame layer 62 can be an oxide layer, such as a silicon dioxide layer, in the BAW devices 92, 94, and 96. When the second raised frame layer 62 is silicon dioxide or another layer with a positive temperature coefficient of frequency, the second raised frame layer 62 can provide temperature compensation for the BAW devices 92, 94, and 96.

In the BAW devices 92, 94, and 96, the second raised frame layer 62 ends at different points toward a center of the BAW devices 92, 94, and 96. As illustrated in FIG. 8A, the second raised frame layer 62 ends at an edge of the engineered region 24e of the piezoelectric layer 24 in the BAW device 92. As illustrated in FIG. 8B, the second raised frame layer 62 extends beyond the engineered region 24e of the piezoelectric layer 24 toward the center of the BAW device 94. As illustrated in FIG. 8C, the second raised frame layer 62 ends over the engineered region 24e of the piezoelectric layer 24 in the BAW device 96.

Although embodiments disclosed herein may be discussed with reference to piezoelectric layers with engineered regions, any suitable principles and advantages disclosed herein can be applied to BAW devices that include less acoustically active material between a pair of electrodes in a frame region compared to material between the pair of electrodes in a main acoustically active region. Such less acoustically active material can include a dielectric material having a relatively low piezoelectric coupling coefficient. In some applications, such less acoustically active material can be a layer of different material than the piezoelectric layer that is between the pair of electrodes in the main acoustically active region of the BAW device.

The BAW devices disclosed herein can be implemented in various applications. BAW devices disclosed herein can be implemented in a variety of applications. Applications of these BAW devices include, but are not limited to, a BAW resonator for a filter that filters an electrical signal, an oscillator such as an oscillator for a clock generator, a sensor (e.g., a gas sensor, a particle sensor, a mass sensor, a pressure or touch sensor, etc.), a delay line such as a delay line for radar and/or instrumentation applications, an actuator, a microphone, and a speaker. Filters that include BAW devices can be implemented in a variety of applications including, but not limited to, mobile phones, base stations, repeaters, relays, wireless communication infrastructure, access points, customer premises equipment (CPE), and distributed antenna systems. Oscillators that include a BAW resonator can replace crystal oscillators in a variety of applications, such as but not limited to electronic timing products. In some applications, an oscillator that includes a BAW resonator and a crystal oscillator can both be implemented. Example applications will now be discussed.

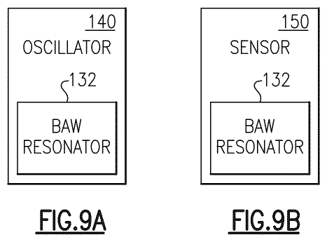

FIG. 9A illustrates that an oscillator 140 can include a BAW resonator 132 according to an embodiment. The oscillator 140 can be any oscillator that could benefit from a BAW wave resonator. For example, the oscillator 140 can be included in a radio frequency front end. The oscillator 140 can be implemented in place of another oscillator, such as a quartz oscillator, in a variety of applications. The oscillator 140 can be provide a frequency reference. The oscillator 140 can generate a local oscillator signal for up converting and/or a down converting a signal.

FIG. 9B illustrates that a sensor 150 can include a BAW resonator 132 according to an embodiment. The sensor 150 can be any sensor that could benefit from a BAW resonator. For example, the sensor 150 can be arranged to sense pressure, to sense temperature, or to sense any other suitable parameter. In some instances, the sensor 150 can be configured for in liquid sensing applications.

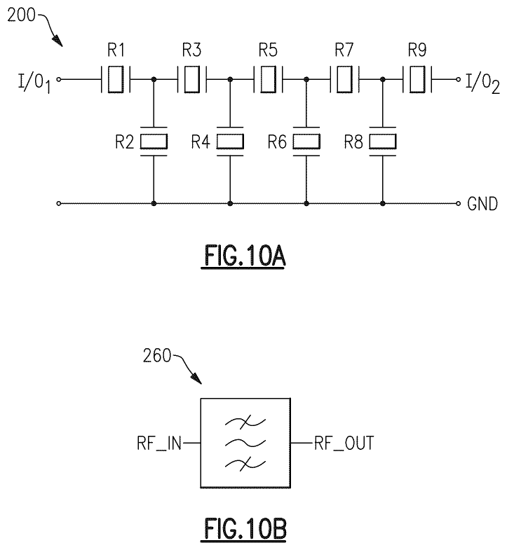

BAW devices disclosed herein can be implemented in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, BAW resonators disclosed herein can be implemented in filters with one or more other types of resonators and/or with passive impedance elements, such as one or more inductors and/or one or more capacitors. An example filter topology will be discussed with reference to FIG. 10A.

FIG. 10A is a schematic diagram of a ladder filter 200 that includes a BAW resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O1 and a second input/output port I/O2. Any suitable number of series acoustic wave resonators can be included in a ladder filter. Any suitable number of shunt acoustic wave resonators can be included in a ladder filter. The first input/output port I/O1 can be a transmit port and the second input/output port I/O2 can be an antenna port. Alternatively, the first input/output port I/O1 can be a receive port and the second input/output port I/O2 can be an antenna port. One or more of the acoustic wave resonators of the ladder filter 200 can include a BAW resonator in accordance with any suitable principles and advantages disclosed herein. All acoustic resonators of the ladder filter 200 can include a BAW resonator in accordance with any suitable principles and advantages disclosed herein in certain instances.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band. A filter that includes a BAW resonator in accordance with any suitable principles and advantages disclosed herein can be arranged to filter a radio frequency signal in any other suitable operating band, such as a WiFi operating band, a Global Positioning System (GPS) operating band, a Bluetooth operating band, a ZigBee operating band, a WiMax operating band, etc.

The BAW resonators disclosed herein can be advantageous for implementing BAW resonators with relatively high Qp and relatively low spur intensity. BAW resonators disclosed herein can have significantly better performance than a variety of other BAW resonators. This can be advantageous in meeting demanding specifications for acoustic wave filters, such as performance specifications for certain 5G applications.

FIG. 10B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

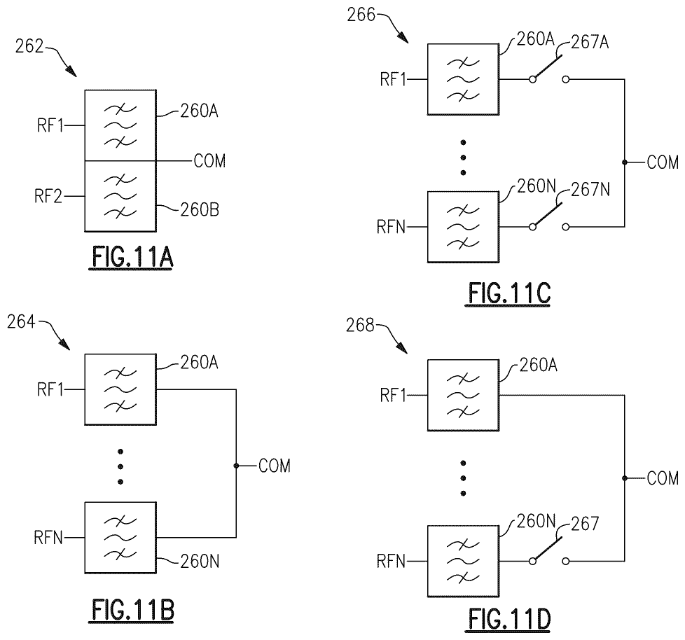

The BAW devices disclosed herein can be implemented in a standalone filter and/or in a filter of any suitable multiplexer. Such filters can be any suitable topology, such as a ladder filter topology. The filter can be a band pass filter arranged to filter a radio frequency signal in a 4G LTE band and/or 5G NR band. The filter can be a band pass filter having a passband corresponding to an operating band of any other suitable wireless communication standard, such as WiFi, etc. Example multiplexers will be discussed with reference to FIGS. 11A to 11D. Any suitable principles and advantages of these multiplexers can be implemented together with each other.

FIG. 11A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 11B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 11C is a schematic diagram of a multiplexer 266 that includes an acoustic wave filter according to an embodiment. The multiplexer 266 is like the multiplexer 264 of FIG. 11B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 11D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

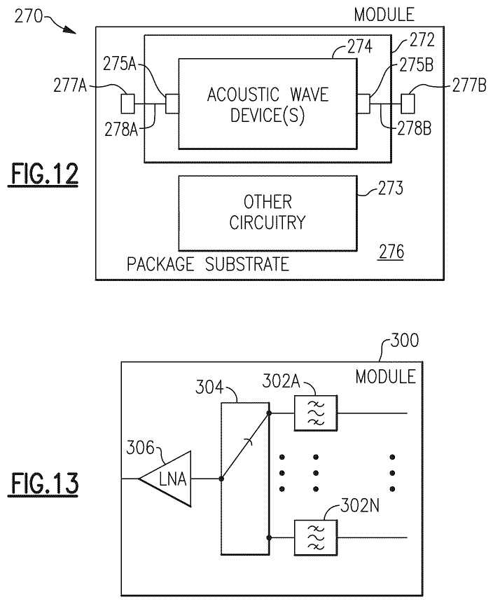

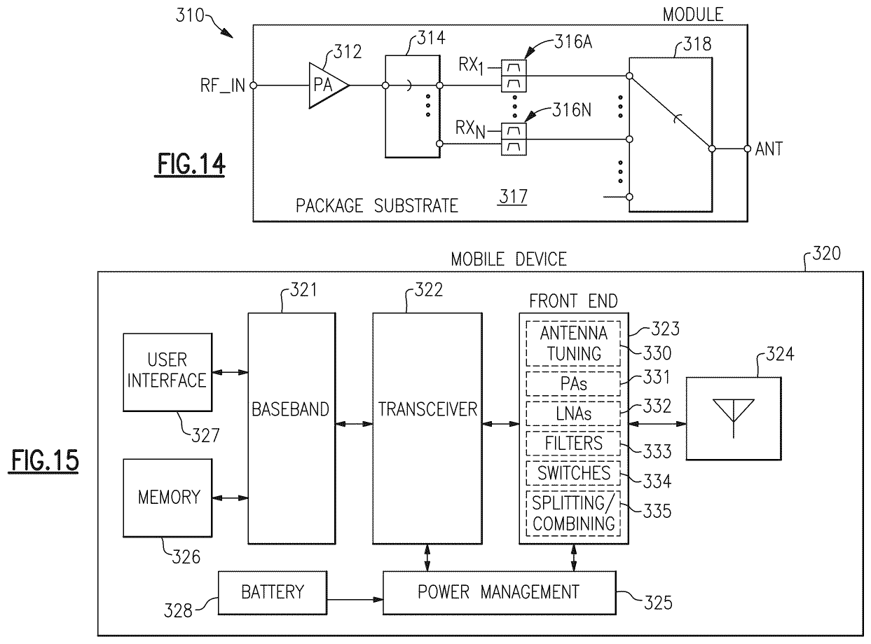

Acoustic wave devices disclosed herein can be implemented in a variety of packaged modules. Some example packaged modules will now be disclosed in which any suitable principles and advantages of the BAW resonators disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 12, 14, and 14 are schematic block diagrams of illustrative packaged modules according to certain embodiments. Any suitable combination of features of these packaged modules can be implemented with each other.

FIG. 12 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW resonators in certain applications.

The acoustic wave component 272 shown in FIG. 12 includes one or more acoustic wave devices 274 and terminals 275A and 275B. The one or more acoustic wave devices 274 include one or more BAW resonators implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 12. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

FIG. 13 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 14 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 14 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW resonator in accordance with any suitable principles and advantages disclosed herein. Similarly, one or more of the receive filters can include a BAW resonator in accordance with any suitable principles and advantages disclosed herein. Although FIG. 14 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

The BAW resonators disclosed herein can be implemented in wireless communication devices. FIG. 15 is a schematic block diagram of a wireless communication device 320 that includes a BAW resonator according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 15 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAs) 331, low noise amplifiers (LNAs) 332, filters 333, switches 334, and signal splitting/combining circuitry 335. However, other implementations are possible. The filters 333 can include one or more acoustic wave filters that include any suitable number of BAW resonators in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 15, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 15, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device having a main acoustically active region and an engineered region around the main acoustically active region in plan view, the bulk acoustic wave device comprising:
an acoustic reflector;
a first electrode;
a second electrode;
a piezoelectric layer positioned between the first electrode and the second electrode over the acoustic reflector, the piezoelectric layer having a lower magnitude effective piezoelectric coefficient in the engineered region than in the main acoustically active region; and
a raised frame layer in the engineered region, a resonance associated with the engineered region being at a lower frequency than a resonant frequency of the main acoustically active region.

2. The bulk acoustic wave device of claim 1 wherein the piezoelectric layer is doped with a dopant.

3. The bulk acoustic wave device of claim 1 wherein the piezoelectric layer is an aluminum nitride layer doped with scandium.

4. The bulk acoustic wave device of claim 1 wherein the piezoelectric layer is an aluminum nitride layer doped with at least 10% scandium.

5. The bulk acoustic wave device of claim 1 wherein the piezoelectric layer is an aluminum nitride layer doped with at least 15% scandium.

6. The bulk acoustic wave device of claim 1 wherein the raised frame layer includes a metal.

7. The bulk acoustic wave device of claim 1 wherein the bulk acoustic wave device includes a recessed frame region positioned between the main acoustically active region and the engineered region.

8. The bulk acoustic wave device of claim 1 wherein the second electrode is positioned farther from the acoustic reflector than the first electrode, and the raised frame layer is positioned between the second electrode and the piezoelectric layer in the engineered region.

9. The bulk acoustic wave device of claim 8 further comprising a second raised frame layer positioned between the second electrode and the piezoelectric layer in the engineered region.

10. The bulk acoustic wave device of claim 9 wherein the second raised frame layer extends closer to the main acoustically active region than the raised frame layer.

11. The bulk acoustic wave device of claim 10 wherein the second raised frame layer extends beyond the engineered region toward the main acoustically active region.

12. The bulk acoustic wave device of claim 10 wherein an end of the second raised frame layer closest to the main acoustically active region terminates in the engineered region.

13. The bulk acoustic wave device of claim 9 wherein the raised frame layer and the second raised frame layer both include an oxide.

14. The bulk acoustic wave device of claim 9 wherein the raised frame layer and the second raised frame layer are layers of a same material.

15. The bulk acoustic wave device of claim 1 wherein the raised frame layer extends beyond the engineered region toward the main acoustically active region.

16. The bulk acoustic wave device of claim 1 wherein the raised frame layer includes a dielectric.

17. An acoustic wave filter for filtering a radio frequency signal, the acoustic wave filter comprising:
a bulk acoustic wave resonator including an acoustic reflector; a first electrode;
a second electrode; a piezoelectric layer positioned between the first electrode and the second electrode over the acoustic reflector, the piezoelectric layer having a lower magnitude effective piezoelectric coefficient in an engineered region than in a main acoustically active region; and a raised frame layer in the engineered region, a resonance associated with the engineered region being at a lower frequency than a resonant frequency of the main acoustically active region; and
a plurality of additional acoustic wave resonators, the bulk acoustic wave resonator and the plurality of additional bulk acoustic wave resonators configured to filter the radio frequency signal.

18. The acoustic wave filter of claim 17 wherein the acoustic wave filter is a bandpass filter.

19. The acoustic wave filter of claim 17 wherein the piezoelectric layer is an aluminum nitride layer doped with scandium.

20. A method of filtering a radio frequency signal, the method comprising:
receiving a radio frequency signal at an input of a filter, the filter including a bulk acoustic wave resonator, the bulk acoustic wave resonator including an acoustic reflector; a first electrode; a second electrode; a piezoelectric layer positioned between the first electrode and the second electrode over the acoustic reflector, the piezoelectric layer having a lower magnitude effective piezoelectric coefficient in an engineered region than in a main acoustically active region; and a raised frame layer in the engineered region, a resonance associated with the engineered region being at a lower frequency than a resonant frequency of the main acoustically active region; and
filtering the radio frequency signal with the filter.
